(19) United States
(12) Patent Application Publication
(10) Pub. No.: US 2021/0091009 A1
(43) Pub. Date: Mar. 25, 2021

(54) Integrated Assemblies Having Barrier Material Between Silicon-Containing Material and Another Material Reactive with Silicon

(71) Applicant: Micron Technology, Inc., Boise, ID (US)

(72) Inventors: Devesh Kumar Datta, Singapore (SG); David Daycock, Woodhaven (SG); Keen Wah Chow, Singapore (SG); Tom George, Boise, ID (US); Justin B. Dorhout, Boise, ID (US); Bingli Ma, Singapore (SG); Rita J. Klein, Boise, ID (US); John Mark Meldrim, Boise, ID (US)

(73) Assignee: Micron Technology, Inc., Boise, ID (US)

(21) Appl. No.: 16/579,577

(22) Filed: Sep. 23, 2019

(51) Int. Cl. H01L 23/532; H01L 23/522; H01L 23/528; H01L 27/11519; H01L 27/11524; H01L 27/11565; H01L 27/1157

(52) U.S. Cl. CPC H01L 23/53209; H01L 23/5226; H01L 23/5283; H01L 27/1157; H01L 27/11524; H01L 27/11565; H01L 27/11519

(57) ABSTRACT

Some embodiments include a memory device having a conductive structure which includes silicon-containing material. A stack is over the conductive structure and includes alternating insulative levels and conductive levels. Channel material pillars extend through the stack and are electrically coupled with the conductive structure. Memory cells are along the channel material pillars. A conductive barrier material is under the silicon-containing material. The conductive barrier material includes one or more metals in combination with one or more nonmetals. An electrical contact is under the conductive barrier material. The electrical contact includes a region reactive with silicon. Silicon is precluded from reaching said region at least in part due to the conductive barrier material. Control circuitry is under the electrical contact and is electrically coupled with the conductive structure through at least the electrical contact and the conductive barrier material.

### TECHNICAL FIELD

Integrated assemblies (e.g., integrated memory). Integrated assemblies having barrier material which blocks silicon migration.

### BACKGROUND

Memory provides data storage for electronic systems. Flash memory is one type of memory, and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of flash memory, and may be configured to comprise vertically-stacked memory cells.

Before describing NAND specifically, it may be helpful to more generally describe the relationship of a memory array within an integrated arrangement. FIG. 1 shows a block diagram of a prior art device 1000 which includes a memory array 1002 having a plurality of memory cells 1003 arranged in rows and columns along with access lines 1004 (e.g., wordlines to conduct signals WL0 through WLm) and first data lines 1006 (e.g., bitlines to conduct signals BL0 through BLn). Access lines 1004 and first data lines 1006 may be used to transfer information to and from the memory cells 1003. A row decoder 1007 and a column decoder 1008 decode address signals A0 through AX on address lines 1009 to determine which ones of the memory cells 1003 are to be accessed. A sense amplifier circuit 1015 operates to determine the values of information read from the memory cells 1003. An I/O circuit 1017 transfers values of information between the memory array 1002 and input/output (I/O) lines 1005. Signals DQ0 through DQN on the I/O lines 1005 can represent values of information read from or to be written into the memory cells 1003. Other devices can communicate with the device 1000 through the I/O lines 1005, the address lines 1009, or the control lines 1020. A memory control unit 1018 is used to control memory operations to be performed on the memory cells 1003, and utilizes signals on the control lines 1020. The device 1000 can receive supply voltage signals Vcc and Vss on a first supply line 1030 and a second supply line 1032, respectively. The device 1000 includes a select circuit 1040 and an input/output (I/O) circuit 1017. The select circuit 1040 can respond, via the I/O circuit 1017, to signals CSEL1 through CSELn to select signals on the first data lines 1006 and the second data lines 1013 that can represent the values of information to be read from or to be programmed into the memory cells 1003. The column decoder 1008 can selectively activate the CSEL1 through CSELn signals based on the A0 through AX address signals on the address lines 1009. The select circuit 1040 can select the signals on the first data lines 1006 and the second data lines 1013 to provide communication between the memory array 1002 and the I/O circuit 1017 during read and programming operations.

The memory array 1002 of FIG. 1 may be a NAND memory array, and FIG. 2 shows a schematic diagram of a three-dimensional NAND memory device 200 which may be utilized for the memory array 1002 of FIG. 1. The device 200 comprises a plurality of strings of charge-storage devices. In a first direction (Z-Z′), each string of charge-storage devices may comprise, for example, thirty-two charge-storage devices stacked over one another with each charge-storage device corresponding to one of, for example, thirty-two tiers (e.g., Tier0-Tier31). The charge-storage devices of a respective string may share a common channel region, such as one formed in a respective pillar of semiconductor material (e.g., polysilicon) about which the string of charge-storage devices is formed. In a second direction (X-X′), each first group of, for example, sixteen first groups of the plurality of strings may comprise, for example, eight strings sharing a plurality (e.g., thirty-two) of access lines (i.e., “global control gate (CG) lines”, also known as wordlines, WLs). Each of the access lines may couple the charge-storage devices within a tier. The charge-storage devices coupled by the same access line (and thus corresponding to the same tier) may be logically grouped into, for example, two pages, such as P0/P32, P1/P33, P2/P34 and so on, when each charge-storage device comprises a cell capable of storing two bits of information. In a third direction (Y-Y′), each second group of, for example, eight second groups of the plurality of strings, may comprise sixteen strings coupled by a corresponding one of eight data lines. The size of a memory block may comprise 1,024 pages and total about 16 MB (e.g., 16 WLs×32 tiers×2 bits=1,024 pages/block, block size=1,024 pages×16 KB/page=16 MB). The number of the strings, tiers, access lines, data lines, first groups, second groups and/or pages may be greater or smaller than those shown in FIG. 2.

FIG. 3 shows a cross-sectional view of a memory block 300 of the 3D NAND memory device 200 of FIG. 2 in an X-X′ direction, including fifteen strings of charge-storage devices in one of the sixteen first groups of strings described with respect to FIG. 2. The plurality of strings of the memory block 300 may be grouped into a plurality of subsets 310, 320, 330 (e.g., tile columns), such as tile columnᵢ, tile columnⱼ and tile columnₖ, with each subset (e.g., tile column) comprising a “partial block” of the memory block 300. A global drain-side select gate (SGD) line 340 may be coupled to the SGDs of the plurality of strings. For example, the global SGD line 340 may be coupled to a plurality (e.g., three) of sub-SGD lines 342, 344, 346 with each sub-SGD line corresponding to a respective subset (e.g., tile column), via a corresponding one of a plurality (e.g., three) of sub-SGD drivers 332, 334, 336. Each of the sub-SGD drivers 332, 334, 336 may concurrently couple or cut off the SGDs of the strings of a corresponding partial block (e.g., tile column) independently of those of other partial blocks. A global source-side select gate (SGS) line 360 may be coupled to the SGSs of the plurality of strings. For example, the global SGS line 360 may be coupled to a plurality of sub-SGS lines 362, 364, 366 with each sub-SGS line corresponding to the respective subset (e.g., tile column), via a corresponding one of a plurality of sub-SGS drivers 322, 324, 326. Each of the sub-SGS drivers 322, 324, 326 may concurrently couple or cut off the SGSs of the strings of a corresponding partial block (e.g., tile column) independently of those of other partial blocks. A global access line (e.g., a global CG line) 350 may couple the charge-storage devices corresponding to the respective tier of each of the plurality of strings. Each global CG line (e.g., the global CG line 350) may be coupled to a plurality of sub-access lines (e.g., sub-CG lines) 352, 354, 356 via a corresponding one of a plurality of sub-string drivers 312, 314 and 316. Each of the sub-string drivers may concurrently couple or cut off the charge-storage devices corresponding to the respective partial block and/or tier independently of those of other partial blocks and/or other tiers. The charge-storage devices corresponding to the respective subset (e.g., partial block) and the respective tier may comprise a “partial tier” (e.g., a single “tile”) of charge-storage devices. The strings corresponding to the respective subset (e.g., partial block) may be coupled to a corresponding one of sub-sources 372, 374 and 376 (e.g., “tile source”) with each sub-source being coupled to a respective power source.

The NAND memory device 200 is alternatively described with reference to a schematic illustration of FIG. 4.

The memory array 200 includes wordlines 202₁ to 202_{N}, and bitlines 228₁ to 228_{M}.

The memory array 200 also includes NAND strings 206₁ to 206_{M}. Each NAND string includes charge-storage transistors 208₁ to 208_{N}. The charge-storage transistors may use floating gate material (e.g., polysilicon) to store charge, or may use charge-trapping material (such as, for example, silicon nitride, metallic nanodots, etc.) to store charge.

The charge-storage transistors 208 are located at intersections of wordlines 202 and strings 206. The charge-storage transistors 208 represent non-volatile memory cells for storage of data. The charge-storage transistors 208 of each NAND string 206 are connected in series source-to-drain between a source-select device (e.g., source-side select gate, SGS) 210 and a drain-select device (e.g., drain-side select gate, SGD) 212. Each source-select device 210 is located at an intersection of a string 206 and a source-select line 214, while each drain-select device 212 is located at an intersection of a string 206 and a drain-select line 215. The select devices 210 and 212 may be any suitable access devices, and are generically illustrated with boxes in FIG. 4.

A source of each source-select device 210 is connected to a common source line 216. The drain of each source-select device 210 is connected to the source of the first charge-storage transistor 208 of the corresponding NAND string 206. For example, the drain of source-select device 210₁ is connected to the source of charge-storage transistor 208₁ of the corresponding NAND string 206₁. The source-select devices 210 are connected to source-select line 214.

The drain of each drain-select device 212 is connected to a bitline (i.e., digit line) 228 at a drain contact. For example, the drain of drain-select device 212₁ is connected to the bitline 228₁. The source of each drain-select device 212 is connected to the drain of the last charge-storage transistor 208 of the corresponding NAND string 206. For example, the source of drain-select device 212₁ is connected to the drain of charge-storage transistor 208_{N} of the corresponding NAND string 206₁.

The charge-storage transistors 208 include a source 230, a drain 232, a charge-storage region 234, and a control gate 236. The charge-storage transistors 208 have their control gates 236 coupled to a wordline 202. A column of the charge-storage transistors 208 are those transistors within a NAND string 206 coupled to a given bitline 228. A row of the charge-storage transistors 208 are those transistors commonly coupled to a given wordline 202.

FIGS. 5 and 5A show a region of an example prior art integrated assembly 10 comprising a portion of an example NAND configuration. The assembly 10 includes a pair of sub-blocks within a tile region. The sub-blocks may be referred to as block regions 11. The sub-blocks and tile may be incorporated into three-dimensional NAND architecture of the types described above in FIGS. 1-4.

A partition 12 extends around the sub-blocks, and separates the sub-blocks from one another and from other sub-blocks. The partition 12 comprises a partition material 14. The partition material 14 may comprise, consist essentially of, or consist of silicon dioxide.

The cross-sectional view of FIG. 5A shows that the assembly 10 includes a stack 16 of alternating conductive levels 18 and insulative levels 20. The levels 18 comprise conductive material 19, and the levels 20 comprise insulative material 21.

The block regions 11 are laterally offset from a staircase region (labeled “Staircase” in FIG. 5), which is a region where electrical contact is made to at least some of the stacked conductive levels 18.

The conductive material 19 may comprise any suitable electrically conductive composition(s), such as, for example, one or more of various metals (e.g., titanium, tungsten, cobalt, nickel, platinum, ruthenium, etc.), metal-containing compositions (e.g., metal silicide, metal nitride, metal carbide, etc.), and/or conductively-doped semiconductor materials (e.g., conductively-doped silicon, conductively-doped germanium, etc.). In some embodiments, the conductive material 19 may include metal (e.g., tungsten) and metal nitride (e.g., tantalum nitride, titanium nitride, etc.).

The insulative material 21 may comprise any suitable composition(s); and in some embodiments may comprise, consist essentially of, or consist of silicon dioxide.

The levels 18 and 20 may be of any suitable thicknesses; and may be the same thickness as one another, or different thicknesses relative to one another. In some embodiments, the levels 18 and 20 may have vertical thicknesses within a range of from about 10 nanometers (nm) to about 400 nm.

In some applications, the lowermost conductive level 18 may be representative of a source-select device (e.g., source-side select gate, SGS); and the upper conductive levels 18 may be representative of wordline levels. The source-select-device level may or may not comprise the same conductive material(s) as the wordline levels.

Although eight conductive levels 18 are shown in FIG. 5A, in practice there may be more than eight conductive levels in the stack 16. For instance, the wordline levels may ultimately correspond to memory cell levels of a NAND configuration. The NAND configuration will include strings of memory cells (i.e., NAND strings), with the number of memory cells in the strings being determined by the number of vertically-stacked wordline levels. The NAND strings may comprise any suitable number of memory cell levels. For instance, the NAND strings may have 8 memory cell levels, 16 and memory cell levels, 32 memory cell levels, 64 memory cell levels, 512 memory cell levels, 1024 memory cell levels, etc. Also, the source-select device may include more than one conductive level.

The stack 16 and the partition 12 are supported over a conductive structure 22. Such conductive structure may comprise semiconductor material 23 (e.g., conductively-doped silicon) over metal-containing material 25 (e.g., WSiₓ, where “x” is greater than 0).

In some applications, the conductive structure 22 may correspond to a source structure (e.g., a structure comprising the so-called common source line 216 of FIG. 4). The source structures of FIGS. 1-4 are referred to as “lines” in accordance with traditional nomenclature, but such lines may be comprised by expanses (plates) rather than being simple wiring lines.

Channel-material pillars 24 extend through the stack 16. The pillars 24 comprise channel material 26. The channel material 26 may be appropriately-doped semiconductor material, and in some applications may comprise silicon. The channel material 26 is spaced from the materials 19 and 21 of the stack 16 by regions 28. Such regions may include one or more of dielectric-barrier material, charge-blocking material, charge-storage material and gate dielectric material (i.e., tunneling material, or simply dielectric material); and may be referred to as cell regions.

The illustrated channel-material structures 24 are hollow channel configurations, with the channel material 26 laterally surrounding an insulative material 29. The insulative material 29 may comprise any suitable composition(s); and in some applications may comprise silicon dioxide. In other applications the channel-material structures 24 may be solid pillars.

Memory cells 30 (only some of which are labeled) are along the conductive levels 18, and include regions of the channel material 26 and the materials within the regions 28 (i.e., the dielectric-barrier material, charge-blocking material, charge-storage material and gate dielectric material). The memory cells 30 may be arranged in vertical NAND strings of the types described in FIGS. 1-4. The memory cells 30 may be referred to as NAND memory cells, and the conductive levels 18 may be referred to as NAND wordline levels.

The conductive structure 22 may be supported by a semiconductor substrate (not shown). The term “semiconductor substrate” means any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductor substrates described above.

The conductive structure 22 is electrically coupled with conductive interconnects 32. The illustrated conductive interconnects are configured as conductive plugs which extend through an insulative material 36 (e.g., one or more of silicon dioxide, silicon nitride, etc.).

The conductive structure 22 is shown to be electrically coupled with CMOS (complementary metal oxide semiconductor) through the interconnects 32. The CMOS may be in any suitable location relative to the conductive structure 22, and in some embodiments may be under such conductive structure. The CMOS may comprise logic and/or other appropriate circuitry for driving the source structure 22 during operation of memory associated with the stack 16. Although the circuitry is specifically identified to be CMOS in the embodiment of FIG. 5A, it is to be understood that such circuitry could be replaced with any other suitable circuitry in other embodiments. The CMOS may be considered to be generally representative of control circuitry.

The interconnects 32 comprise conductive material 34. In some applications, the conductive material 34 may be reactive with silicon. For instance, at least some of the conductive material 34 may consist essentially of, or consist of tungsten. Additionally, the conductive material 25 of the structure 22 may be a silicon-containing material (e.g., a metal silicide, such as tungsten silicide). A problem which may occur is that silicon may migrate (out-diffuse) from the silicon-containing material 25 to the reactive material 34 and may undesirably modify the reactive material. For instance, the silicon may form a silicide from metal of the reactive material 34, which may undesirably reduce conductivity of the conductive interconnects 32. Additionally, the reaction of the material 34 with the silicon may alter the physical dimensions of the interconnects 32 (e.g., may result in volumetric expansion of the conductive material of the interconnects 32), which may lead to buckling and/or other problematic perturbation of the structure 22. The blocks 11 may be very tall, and the perturbation of the structure 22 may lead to bending of such blocks, and even to collapse of the blocks across the intervening regions between the blocks.

It would be desirable to alleviate or prevent the problematic silicon migration into the conductive material of the interconnects 32.

### BRIEF DESCRIPTION OF THE DRAWINGS

FIG. 1 shows a block diagram of a prior art memory device having a memory array with memory cells.

FIG. 2 shows a schematic diagram of the prior art memory array of FIG. 1 in the form of a 3D NAND memory device.

FIG. 3 shows a cross-sectional view of the prior art 3D NAND memory device of FIG. 2 in an X-X′ direction.

FIG. 4 is a schematic diagram of a prior art NAND memory array.

FIG. 5 is a diagrammatic top view of a region of a prior art integrated assembly illustrating an example architecture.

FIG. 5A is a diagrammatic cross-sectional side view of the prior art integrated assembly of FIG. 5 along the line A-A of FIG. 5.

FIG. 6 is a diagrammatic cross-sectional side view of a region of an example integrated assembly along the same cross-section as FIG. 5A.

FIG. 7 is a diagrammatic cross-sectional side view of a region of an example integrated assembly along the same cross-section as FIG. 5A.

FIGS. 7A and 7B are diagrammatic top-down views along the lines A-A and B-B of FIG. 7, respectively.

FIG. 8 is a diagrammatic cross-sectional side view of a region of an example structure.

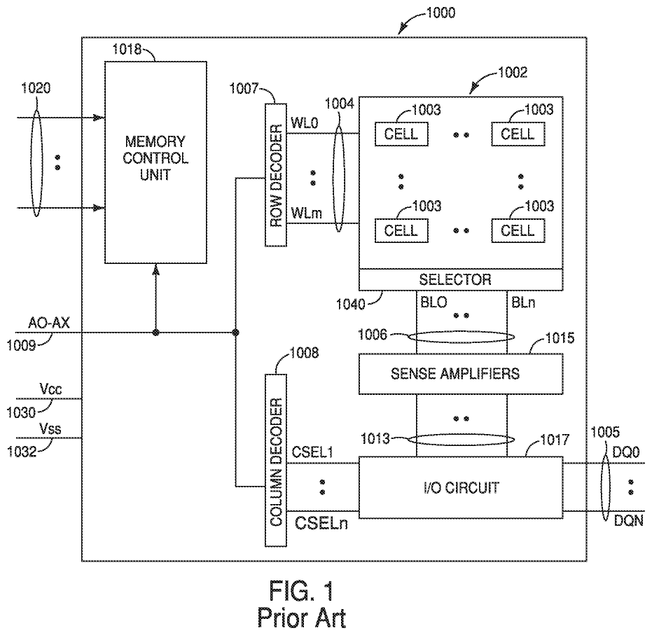

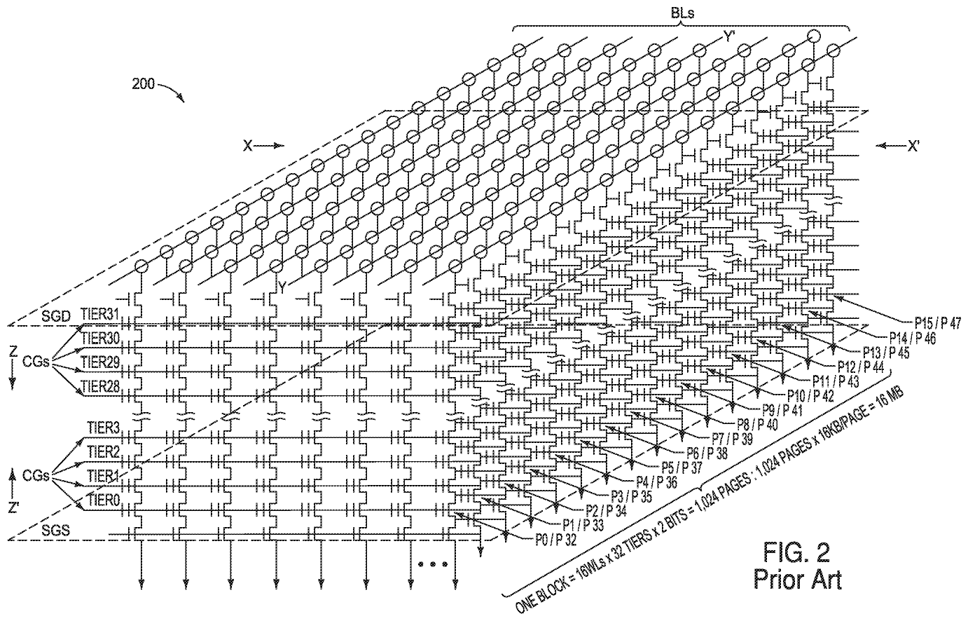

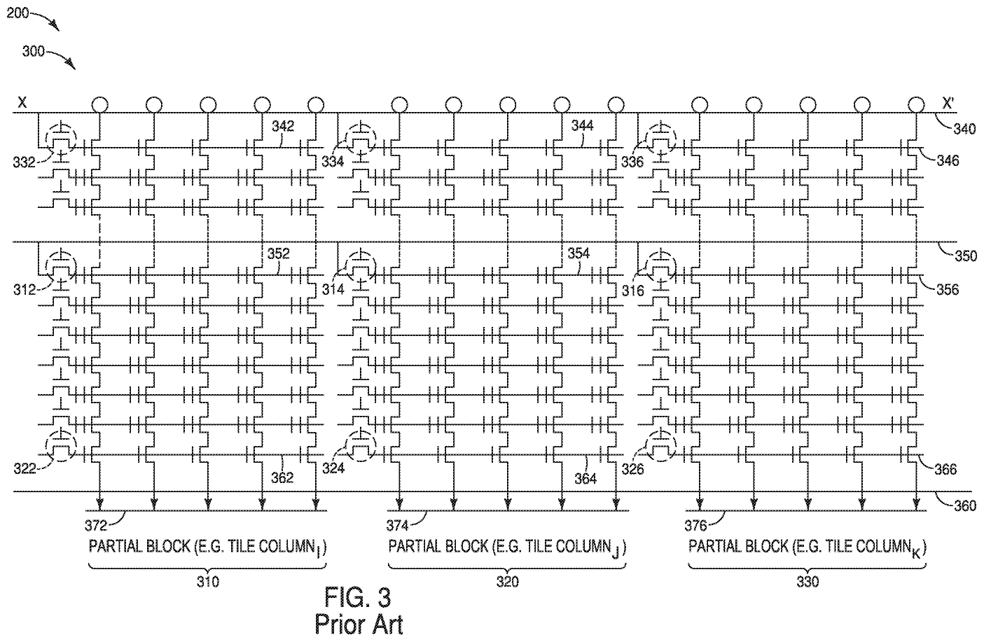

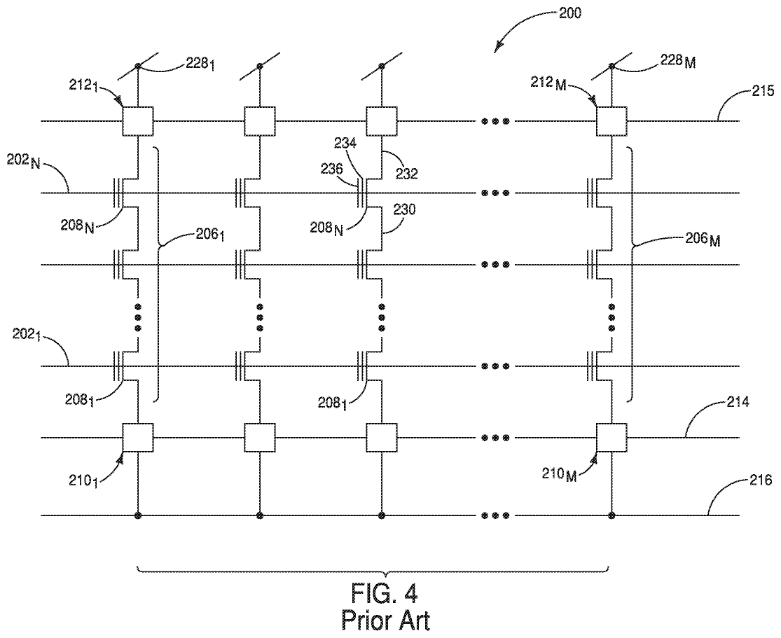

### DETAILED DESCRIPTION OF THE ILLUSTRATED EMBODIMENTS

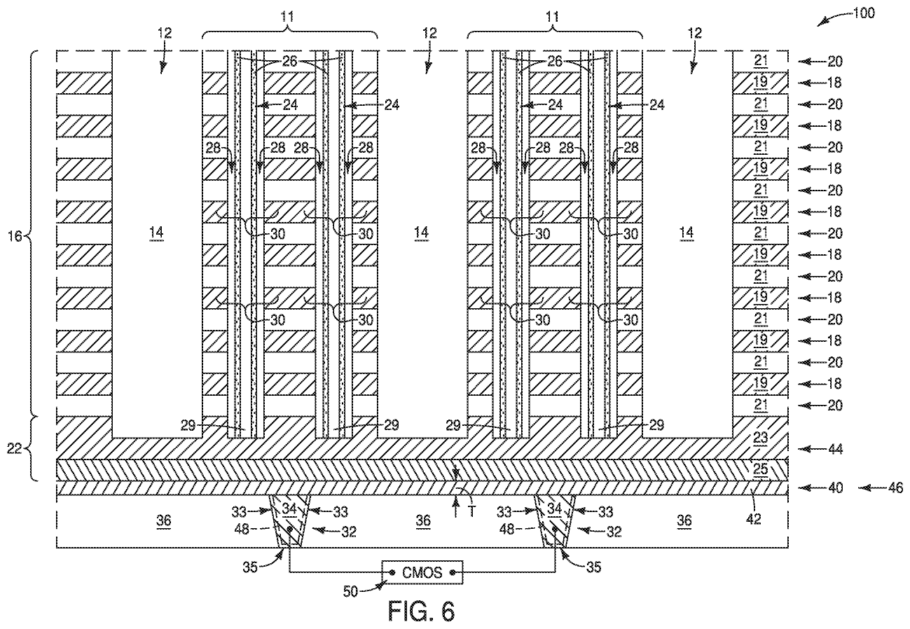

Some embodiments include integrated assemblies having silicon-containing material and having reactive material which may undesirably react with silicon if the silicon were to migrate from the silicon-containing material to the reactive material. The integrated assemblies include conductive barrier material between the silicon-containing material and the reactive material, and configured to preclude silicon migration from the silicon-containing material to the reactive material. The conductive barrier material may electrically couple the reactive material with the silicon-containing material. Some embodiments include memory devices having silicon-containing source structures which are electrically coupled with control circuitry (e.g., CMOS) through electrical interconnects having regions reactive with silicon. The memory devices include conductive barrier material between the silicon-containing source material and the regions reactive with silicon, with the conductive barrier material being configured to block undesired silicon migration. Example embodiments are described with reference to FIGS. 6-8.

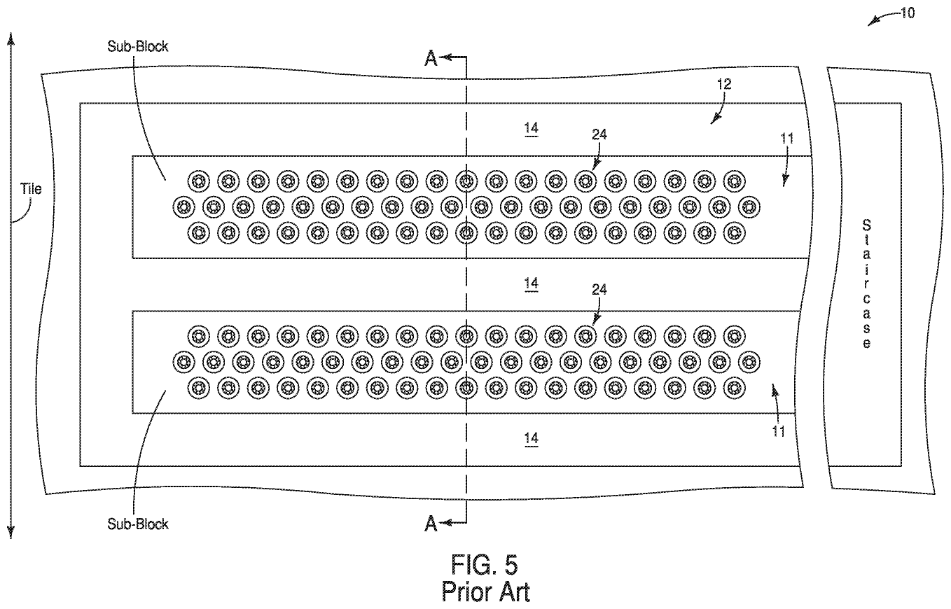

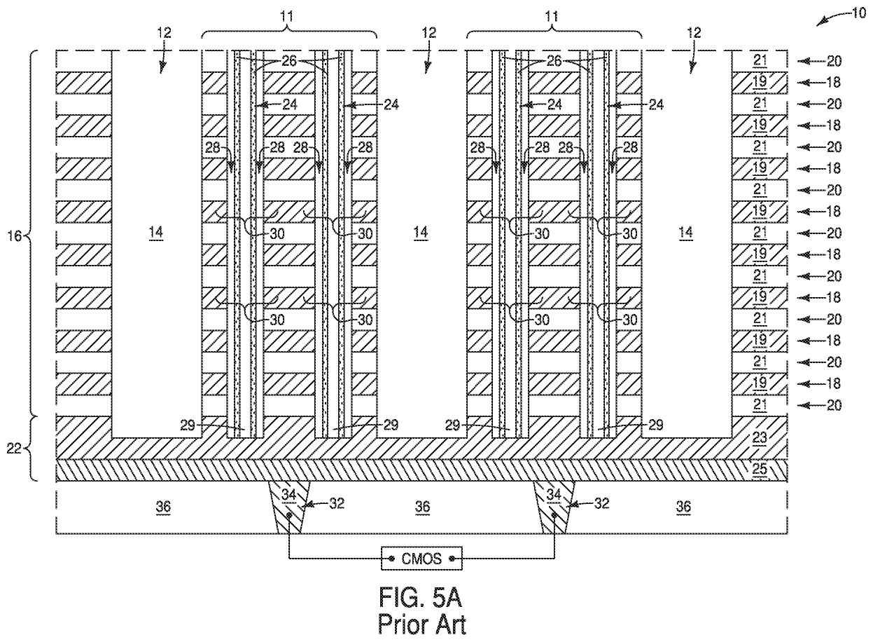

Referring to FIG. 6, an integrated assembly 100 is shown to comprise many of the structures and features described above relative to FIG. 5A. Specifically, the integrated assembly 100 may be considered to comprise a memory device which includes the stack 16 of alternating conductive levels 18 and insulative 20. The channel material pillars 24 extend through such stack, and are electrically coupled with the conductive structure 22. The memory cells 30 are along the channel material pillars. However, the integrated assembly 100 of FIG. 6 differs from the assembly 10 of FIG. 5A in that a conductive barrier 40 is provided between the silicon-containing material 25 and the conductive material 34 of the electrical contacts (interconnects) 32.

The conductive barrier 40 comprises conductive barrier material 42. In the illustrated embodiment, the conductive structure 22 is configured as an expanse which extends along the cross-section of FIG. 6, and which also extends in and out of the page relative to the cross-section of FIG. 6. Such expanse may be referred to as a first expanse 44. The conductive barrier material 42 is configured as a second expanse 46 which is coextensive with the first expanse 44. In some embodiments, the barrier material 42 may be considered to be part of the conductive structure 22 rather than being referred to as being a separate expanse relative to the conductive structure 22.

In the illustrated embodiment, the conductive barrier material 42 is directly against a bottom surface of the conductive material 25, is also directly against upper surfaces of the interconnects 32.

The conductive barrier material 42 may comprise one or more metals in combination with one or more nonmetals. The metals of the conductive barrier material 42 may be selected from the group consisting of aluminum (Al), cobalt (Co), molybdenum (Mo), nickel (Ni), ruthenium (Ru), tantalum (Ta), titanium (Ti) and tungsten (W). The nonmetals of the conductive barrier material 42 may be selective from the group consisting of nitrogen (N), boron (B) and carbon (C). A total concentration of the one or more nonmetals within the conductive barrier material 24 may be at least about 20 atomic percent (at %); and in some embodiments may be within a range of from about 20 at % to about 70 at %. Although the barrier material 42 is shown as a single homogenous composition, it is to be understood that in some embodiments the barrier material 42 may comprise two or more layers of different compositions relative to one another (i.e., may comprise a laminate configuration). In such embodiments, one or more of the layers of the barrier material 42 could be deposited with a different deposition process than one or more of the other layers of the barrier material 42.

In some embodiments, the conductive barrier material 42 may comprise, consist essentially of, or consist of one or more of CoN, TiN and WN, where the chemical formulas indicate primary constituents rather than specific stoichiometries. In some embodiments, the conductive barrier material 42 may comprise one or both of tungsten and titanium, and may further comprise one or more of boron, carbon and nitrogen.

The conductive barrier 40 may have any suitable thickness, T, between the interconnects 32 and the silicon-containing material 25; and in some embodiments such thickness may be at least about 5 nm, at least about 30 nm, at least about 100 nm, or within a range of from at least about 5 nm to at least about 1000 nm.

The electrical contacts 32 are configured as conductive plugs extending into the insulative material 36. Such conductive plugs comprise sidewall surfaces 33 and bottom surfaces 35.

The electrical contacts 32 are shown to comprise a single homogeneous material 34. In some embodiments, the electrical contacts may comprise two or more different materials. For instance, in some embodiments the contacts may comprise a conductive liner 48 extending along the sidewall surfaces 33 and the bottom surfaces 35, and partially surrounding the conductive material 34. The conductive material 34 may be considered to correspond to regions of the electrical contacts which are reactive with silicon. In some embodiments, the reactive material 34 may comprise, consist essentially of, or consist of one or more metals selected from the group consisting of cobalt, nickel, molybdenum, tantalum, titanium, ruthenium and tungsten.

In some embodiments, the reactive material 34 may comprise only a single metal. Such metal may be referred to as being “substantially elemental” to indicate that the metal is pure to within reasonable tolerances of fabrication and measurement. For instance, in some embodiments the reactive material 34 may comprise, consist essentially of, or consist of tungsten.

In some embodiments, the reactive material 34 may comprise two or more metals. In such embodiments, the reactive material 34 may be considered to consist essentially of, or consist of a mixture of two or more metals; where the term “mixture” includes alloys.

The metals of the reactive material 34 may be referred to as second metals to distinguish them from the first metals of the conductive barrier material 42.

To the extent that the conductive liners 48 are present, such conductive liners may comprise any suitable composition(s); and in some embodiment may comprise, consist essentially of, or consist of one or more of TaN, WN and TiN, where the chemical formulas indicate primary constituents rather than specific stoichiometries.

The silicon-containing material 25 of the conductive structure 22 may comprise any suitable composition(s); and in some embodiments may comprise, consist essentially of, or consist of one or more metal silicides. For instance, the material 25 may comprise, consist essentially of, or consist of tungsten silicide.

The conductive barrier 40 may preclude silicon from reaching the reactive material 34. In some embodiments, the conductive barrier material 42 may be the only material between the reactive material 34 and the silicon-containing material 25 (as shown), and accordingly may be entirely responsible for precluding silicon from reaching the reactive material 34. The barrier material 42 may thus protect the reactive material 34 from silicon which may be migrating from the silicon-containing material 25.

Control circuitry 50 (e.g., CMOS circuitry) is coupled with conductive structure 22 through the electrical contacts 32 and the conductive barrier material 42. The control circuitry 50 may be under the conductive structure 22, and accordingly the integrated assembly 100 may correspond to a so-called CMOS-under-array configuration. The control circuitry may be within a separate deck relative to the stack 16 and conductive structure 22, with such deck being vertically offset relative to the deck comprising the stack 16 and the conductive structure 22. The deck comprising the control circuitry 50 may be part of a separate semiconductor die relative to the die comprising the stack 16 and the conductive structure 22, or may be part of the same die that comprises the stack 16 and the conductive structure 22.

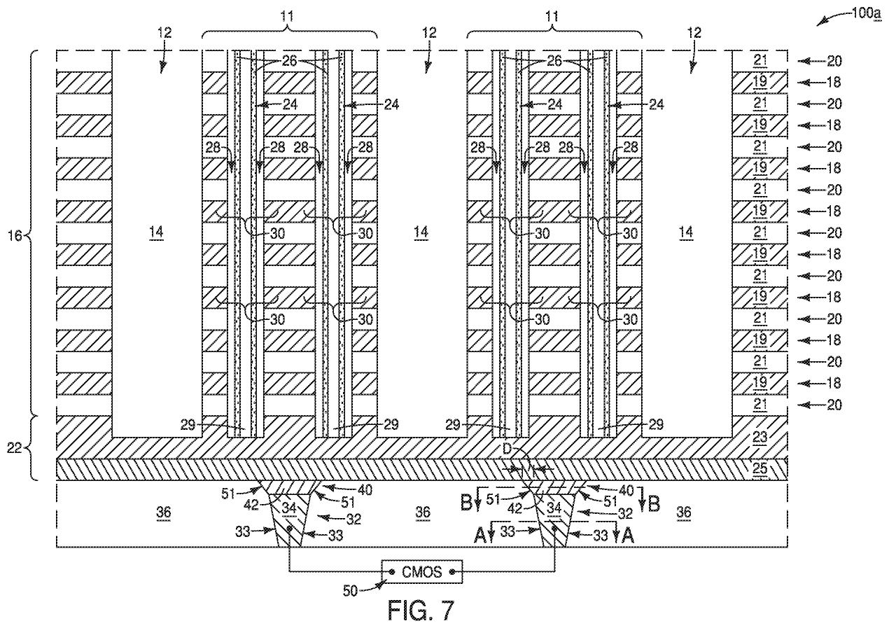

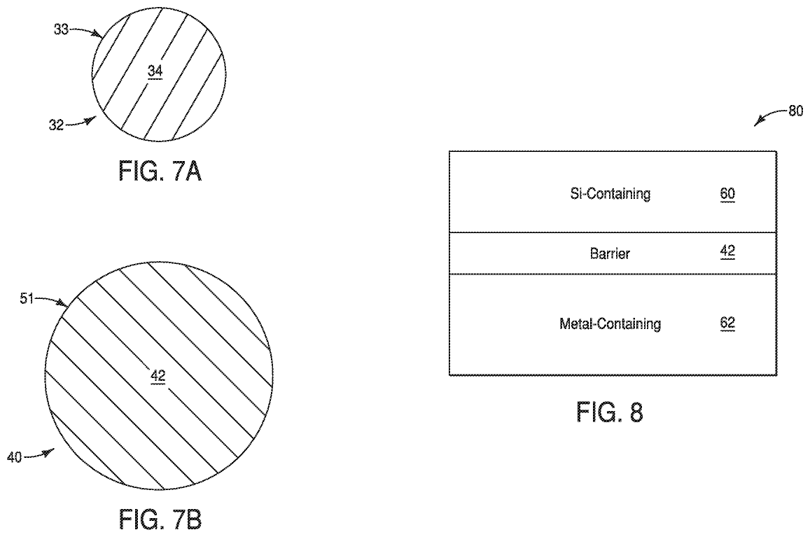

Referring next to FIG. 7, such shows an integrated assembly 100a which is similar to the integrated assembly 100 of FIG. 6, except that the conductive barrier material 42 is configured as segments associated with the electrical contacts 32. In some embodiments, the electrical contacts 32 may be considered to be configured as first conductive plugs, and the conductive barrier material 42 may be considered to be configured as second conductive plugs which are over the first conductive plugs. The first conductive plugs (i.e., the electrical contacts 32) comprise the sidewalls 33, and the second conductive plugs (i.e., the segments of the conductive barrier material 42) comprise sidewalls 51. The sidewalls 51 may be considered to be substantially coextensive with the sidewalls 33. In the illustrated embodiment, the sidewalls 33 are tapered and the sidewalls 51 are also tapered. The sidewalls 51 may extend laterally outwardly beyond outermost lateral edges of the sidewalls 33 (as shown), or may extend substantially vertically from outermost lateral edges of the sidewalls 33, or may even extend laterally inwardly relative to the outermost lateral edges of the sidewalls 33. If the sidewalls 51 extend outwardly relative to the sidewalls 33 (as shown), they may extend outwardly to a distance D beyond the outermost edges of the sidewalls 33 of at least about 5 nm, at least about 10 nm, at least about 20 nm, at least about 50 nm, etc.

FIGS. 7A and 7B shows cross-sections along the lines A-A and B-B of FIG. 7, and show that the features 32 and 40 may have closed shapes along top-down views. In the illustrated embodiment, such closed shapes are circular. In other embodiments, the structures 32 and 40 may have other shapes in top-down view; including, for example, elliptical shapes, square shapes, etc.

The optional liners 48 (FIG. 6) are not shown in FIG. 7 in order to simplify the drawing, but it is to be understood that such liners may be optionally present in the embodiment of FIG. 7 analogously to the optional presence of such liners in the embodiment of FIG. 6.

In some embodiments, the conductive barrier material 42 may be utilized in other applications besides the illustrated applications of FIGS. 6 and 7. FIG. 8 generically illustrates an example application for the conductive barrier material 42. Specifically, FIG. 8 shows an integrated assembly 80 having the conductive barrier material 42 provided between a silicon-containing first material 60 and a metal-containing second material 62. As an example, the silicon-containing material 60 may comprise, consist essentially of, or consist of silicon in any suitable crystalline form (e.g., one or more of amorphous, polycrystalline and monocrystalline), which may or may not be doped. As another example, the silicon-containing material 60 may comprise metal in combination with silicon (e.g., may comprise, consist essentially of, or consist of titanium silicide, tungsten silicide, tantalum silicide, and/or any other suitable metal silicide). The metal-containing material 62 may comprise a metal which reacts with silicon, and may comprise any of the metals described above as being suitable for utilization in the material 34 of the integrated assemblies of FIGS. 6 and 7.

The conductive barrier material 42 may block undesired silicon migration from the material 60 to the material 62, while also electrically coupling the materials 60 and 62 with one another.

The assemblies and structures discussed above may be utilized within integrated circuits (with the term “integrated circuit” meaning an electronic circuit supported by a semiconductor substrate); and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

Unless specified otherwise, the various materials, substances, compositions, etc. described herein may be formed with any suitable methodologies, either now known or yet to be developed, including, for example, atomic layer deposition (ALD), chemical vapor deposition (CVD), physical vapor deposition (PVD), etc.

The terms “dielectric” and “insulative” may be utilized to describe materials having insulative electrical properties. The terms are considered synonymous in this disclosure. The utilization of the term “dielectric” in some instances, and the term “insulative” (or “electrically insulative”) in other instances, may be to provide language variation within this disclosure to simplify antecedent basis within the claims that follow, and is not utilized to indicate any significant chemical or electrical differences.

The terms “electrically connected” and “electrically coupled” may both be utilized in this disclosure. The terms are considered synonymous. The utilization of one term in some instances and the other in other instances may be to provide language variation within this disclosure to simplify antecedent basis within the claims that follow.

The particular orientation of the various embodiments in the drawings is for illustrative purposes only, and the embodiments may be rotated relative to the shown orientations in some applications. The descriptions provided herein, and the claims that follow, pertain to any structures that have the described relationships between various features, regardless of whether the structures are in the particular orientation of the drawings, or are rotated relative to such orientation.

The cross-sectional views of the accompanying illustrations only show features within the planes of the cross-sections, and do not show materials behind the planes of the cross-sections, unless indicated otherwise, in order to simplify the drawings.

When a structure is referred to above as being “on”, “adjacent” or “against” another structure, it can be directly on the other structure or intervening structures may also be present. In contrast, when a structure is referred to as being “directly on”, “directly adjacent” or “directly against” another structure, there are no intervening structures present. The terms “directly under”, “directly over”, etc., do not indicate direct physical contact (unless expressly stated otherwise), but instead indicate upright alignment.

Structures (e.g., layers, materials, etc.) may be referred to as “extending vertically” to indicate that the structures generally extend upwardly from an underlying base (e.g., substrate). The vertically-extending structures may extend substantially orthogonally relative to an upper surface of the base, or not.

Some embodiments include an integrated assembly having a silicon-containing first material, and having a second material proximate the silicon-containing first material. A conductive barrier material is between the silicon-containing first material and the second material and is configured to block silicon migration from the silicon-containing first material to the second material. The conductive barrier material includes one or more metals in combination with one or more nonmetals selected from the group consisting of nitrogen, boron and carbon.

Some embodiments include a memory device having a conductive structure which includes silicon-containing material. A stack is over the conductive structure and includes alternating insulative levels and conductive levels. Channel material pillars extend through the stack and are electrically coupled with the conductive structure. Memory cells are along the channel material pillars. A conductive barrier material is under the silicon-containing material and is directly against the silicon-containing material. The conductive barrier material includes one or more metals in combination with one or more nonmetals. The one or more nonmetals are selected from the group consisting of boron, carbon and nitrogen. An electrical contact is under the conductive barrier material and is directly against the conductive barrier material. The electrical contact includes a region reactive with silicon. Silicon is precluded from reaching said region at least in part due to the conductive barrier material. Control circuitry is under the electrical contact and is electrically coupled with the conductive structure through at least the electrical contact and the conductive barrier material.

Some embodiments include a memory device having a conductive structure which comprises conductively-doped silicon over tungsten silicide. A stack is over the conductive structure and comprises alternating insulative levels and conductive levels. Channel material pillars extend through the stack and are electrically coupled with the conductive structure. Memory cells are along the channel material pillars. A conductive barrier material is under the tungsten silicide and is directly against the tungsten silicide. The conductive barrier material comprises one or both of W and Ti in combination with one or more of boron, carbon and nitrogen. The conductive barrier material has a thickness of at least about 5 nm. An electrical contact is under the conductive barrier material and is directly against the conductive barrier material. The electrical contact comprises a region which consist essentially of one or more metals. Control circuitry is under the electrical contact and is electrically coupled with the conductive structure through at least the electrical contact and the conductive barrier material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. An integrated assembly, comprising:
a silicon-containing first material;
a second material proximate the silicon-containing first material; and
a conductive barrier material between the silicon-containing first material and the second material and being configured to block silicon migration from the silicon-containing first material to the second material; the conductive barrier material comprising one or more metals in combination with one or more nonmetals selected from the group consisting of nitrogen, boron and carbon.

2. The integrated assembly of claim 1 wherein the conductive barrier material has a thickness between the first and second materials of at least about 5 nm.

3. The integrated assembly of claim 1 wherein the conductive barrier material has a thickness between the first and second materials of at least about 100 nm.

4. The integrated assembly of claim 1 wherein the conductive barrier material has a thickness between the first and second materials which is within a range of from at least about 5 nm to at least about 1000 nm.

5. The integrated assembly of claim 1 wherein said one or more metals comprise one or more of Al, Co, Mo, Ni, Ru, Ta, Ti and W.

6. The integrated assembly of claim 1 wherein the second material consists essentially of one or more of Co, Ni, Mo, Ta, Ti, Ru and W.

7. The integrated assembly of claim 1 wherein the second material consists essentially of W.

8. The integrated assembly of claim 1 wherein a total concentration of said one or more nonmetals within the conductive barrier material is at least about 20 at %.

9. The integrated assembly of claim 1 wherein a total concentration of said one or more nonmetals within the conductive barrier material is within a range of from about 20 at % to about 70 at %.

10. The integrated assembly of claim 1 wherein the one or more nonmetals include the nitrogen.

11. The integrated assembly of claim 1 wherein the conductive barrier material comprises one or both of TiN and WN, where the chemical formulas indicate primary constituents rather than specific stoichiometries.

12. A memory device, comprising:
a conductive structure comprising silicon-containing material;
a stack over the conductive structure and comprising alternating insulative levels and conductive levels;
channel material pillars extending through the stack and being electrically coupled with the conductive structure;
memory cells along the channel material pillars;
a conductive barrier material under the silicon-containing material and being directly against the silicon-containing material; the conductive barrier material comprising one or more metals in combination with one or more nonmetals; the one or more nonmetals being selected from the group consisting of boron, carbon and nitrogen;
an electrical contact under the conductive barrier material and being directly against the conductive barrier material; said electrical contact comprising a region reactive with silicon and protected from the silicon of the silicon-containing material by the conductive barrier material; and
control circuitry under the electrical contact and being electrically coupled with the conductive structure through at least the electrical contact and the conductive barrier material.

13. The memory device of claim 12 wherein said one or more metals of the conductive barrier material are one or more first metals; and wherein said region consists essentially of one or more second metals.

14. The memory device of claim 12 wherein said region consists essentially of tungsten.

15. The memory device of claim 12 wherein the conductive structure is a first expanse, and wherein the conductive barrier material is a second expanse coextensive with the first expanse.

16. The memory device of claim 12 wherein the conductive structure is an expanse, wherein the electrical contact is a first conductive plug under the expanse and having first sidewalls along a cross-section, and wherein the conductive barrier material is a second conductive plug between the expanse and the first conductive plug and having second sidewalls along the cross-section; the second sidewalls being substantially coextensive with the first sidewalls.

17. The memory device of claim 16 wherein said region comprises tungsten; and wherein the first conductive plug comprises a conductive liner partially surrounding the region; the conductive liner being along the first and second sidewalls and being along a bottom of the first conductive plug.

18. The memory device of claim 17 wherein the conductive liner comprises one or more of TaN, WN and TiN, where the chemical formulas indicate primary constituents rather than specific stoichiometries.

19. The memory device of claim 16 wherein the first sidewalls are tapered.

20. The memory device of claim 19 wherein the second sidewalls are tapered.

21. The memory device of claim 12 wherein the control circuitry comprises CMOS.

22. The memory device of claim 12 wherein the silicon-containing material is a metal silicide.

23. The memory device of claim 12 wherein the silicon-containing material comprises tungsten silicide.

24. A memory device, comprising:
a conductive structure comprising conductively-doped silicon over tungsten silicide;
a stack over the conductive structure and comprising alternating insulative levels and conductive levels;
channel material pillars extending through the stack and being electrically coupled with the conductive structure;
memory cells along the channel material pillars;
a conductive barrier material under the tungsten silicide and being directly against the tungsten silicide; the conductive barrier material comprising one or both of W and Ti, and comprising one or more of boron, carbon and nitrogen;
an electrical contact under the conductive barrier material and being directly against the conductive barrier material; said electrical contact comprising a region which consist essentially of one or more metals; the conductive barrier material having a thickness of at least about 5 nm between the electrical contact and the tungsten silicide; and
control circuitry under the electrical contact and being electrically coupled with the conductive structure through at least the electrical contact and the conductive barrier material.

25. The memory device of claim 24 wherein said region consists essentially of tungsten.

26. The memory device of claim 24 wherein the conductive barrier material consists essentially of the WN, where the chemical formula indicates primary constituents rather than a specific stoichiometry.

27. The memory device of claim 24 wherein the conductive barrier material consists essentially of the TiN, where the chemical formula indicates primary constituents rather than a specific stoichiometry.

28. The memory device of claim 24 wherein the conductive structure is a first expanse, and wherein the conductive barrier material is a second expanse coextensive with the first expanse.

29. The memory device of claim 24 wherein the conductive structure is an expanse, wherein the electrical contact is a first conductive plug under the expanse and having first sidewalls along a cross-section, and wherein the conductive barrier material is a second conductive plug between the expanse and the first conductive plug and having second sidewalls along the cross-section; the second sidewalls being substantially coextensive with the first sidewalls.
